(19) United States
(12) Patent Application Publication
(10) Pub. No.: US 2014/0238737 A1
(43) Pub. Date: Aug. 28, 2014

(54) Reducing Inductive Heating

(71) Applicant: NOKIA CORPORATION, Espoo (FI)

(72) Inventor: Juha Reinhold Backman, Espoo (FI)

(73) Assignee: Nokia Corporation, Espoo (FI)

(21) Appl. No.: 13/778,781

(22) Filed: Feb. 27, 2013

(51) Int. Cl. H05K 9/00

(52) U.S. Cl. CPC H05K 9/002
USPC 174/396

(57) ABSTRACT

An audio transducer apparatus including a component having a first material; and a heating reduction system configured to reduce induced heating in the component. The heating reduction system includes a member at least partially surrounding the component. The member includes a material which has an electrical conductivity that is higher than an electrical conductivity of the first material to thereby reduce induced heating in the component.

### BACKGROUND

1. Technical Field

The exemplary and non-limiting embodiments relate generally to preventing heat from being generated in a component and, more particularly, to heat caused by eddy currents.

2. Brief Description of Prior Developments

Portable electronic devices are known which have a battery and an induction charging system for charging the battery. However, inductive charging can result in surface currents being induced in other members of the device, and can cause a significant additional temperature increase in components and in the interior of the device being charged.

### SUMMARY

The following summary is merely intended to be exemplary. The summary is not intended to limit the scope of the claims.

In accordance with one aspect, an example apparatus includes an audio transducer apparatus including a component having a first material; and a heating reduction system configured to reduce induced heating in the component. The heating reduction system includes a member at least partially surrounding the component. The member includes a material which has an electrical conductivity that is higher than an electrical conductivity of the first material to thereby reduce induced heating in the component.

In accordance with another aspect, an example method comprises providing at least one component comprising a first material susceptible to heating by induced eddy currents from magnetic fields; and connecting a heating reduction system to the component, where the heating reduction system is configured to reduce heating in the component, where the heating reduction system comprises a member at least partially surrounding the component, where the member comprises a material which has an electrical conductivity that is higher than an electrical conductivity of the first material to reduce heating in the component.

In accordance with another aspect, an example apparatus comprises a housing; a rechargeable battery in the housing; an induction charging system in the housing coupled to the rechargeable battery; a component in the housing, where the component comprises a first material susceptible to heating by induced eddy currents from induction charging magnetic fields generated externally from the apparatus; and an eddy current heating reduction system configured to reduce induced eddy current heating in the component by the induction charging magnetic fields. The eddy current heating reduction system comprises a member at least partially surrounding the component. The member comprises a second material which has an electrical conductivity that is higher than an electrical conductivity of the first material. The member is configured to allow an induced current density to be formed in the member from the induction charging magnetic fields which is higher than an induced current density formed in the component from the induction charging magnetic fields to reduce induced eddy current heating in the component by the induction charging magnetic fields.

### BRIEF DESCRIPTION OF THE DRAWINGS

The foregoing aspects and other features are explained in the following description, taken in connection with the accompanying drawings, wherein:

FIG. 1 is a front view of an example embodiment;

FIG. 2 is a side view of the example shown in FIG. 1;

FIG. 3 is a diagram illustrating connection of the apparatus shown in FIG. 1 to a charging station for inductive charging;

FIG. 4 is a cross sectional view of a magnet assembly in the apparatus shown in FIG. 1;

FIG. 5 is an exploded perspective view of the magnet assembly shown in FIG. 4;

FIG. 6 a schematic sectional view of some of the components of the apparatus shown on FIG. 1;

FIG. 7 is a diagram illustrating heat generation in a component with the an eddy current heating reduction system of the apparatus shown in FIG. 1 and without the an eddy current heating reduction system;

FIG. 8 is a diagram illustrating steps of one type of example method;

FIG. 9 is a top view of the shielding member shown in FIG. 6;

FIG. 10 is a top view of an alternate example of a shielding member;

FIG. 11 is a schematic sectional view of some of the components of an example embodiment similar to FIG. 6.

### DETAILED DESCRIPTION OF EMBODIMENTS

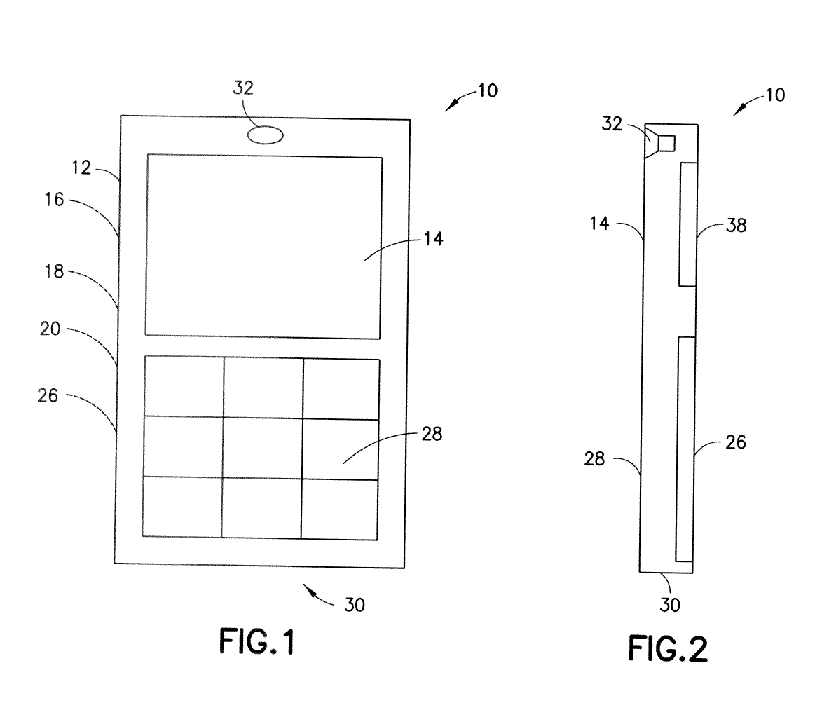

Referring to FIG. 1, there is shown a front view of a device or apparatus 10 incorporating features of an example embodiment. Although the features will be described with reference to the example embodiments shown in the drawings, it should be understood that features can be embodied in many alternate forms of embodiments. In addition, any suitable size, shape or type of elements or materials could be used.

Referring also to FIG. 2, the apparatus 10 may be a hand-held communications device which includes a telephone application. The apparatus 10 may comprise an Internet browser application, camera application, video recorder application, music player and recorder application, email application, navigation application, gaming application, and/or any other suitable electronic device application. The apparatus 10, in this example embodiment, comprises a housing 12, a display 14, a receiver 16, a transmitter 18, a rechargeable battery 26, and a controller 20 which can include at least one processor, at least one memory, and software. However, all of these features are not necessary to implement the features described below.

The display 14 in this example may be a touch screen display which functions as both a display screen and as a user input. However, features described herein may be used in a display which does not have a touch, user input feature. The user interface may also include a keypad 28. However, the keypad might not be provided if a touch screen is provided. The electronic circuitry inside the housing 12 may comprise a printed wiring board (PWB) having components such as the controller 20 thereon. The circuitry may include a sound transducer 30 provided as a microphone and a sound transducer 32 provided as a speaker or earpiece. The housing 12 may have sound holes for sound to travel to and from the sound transducers through the housing 12.

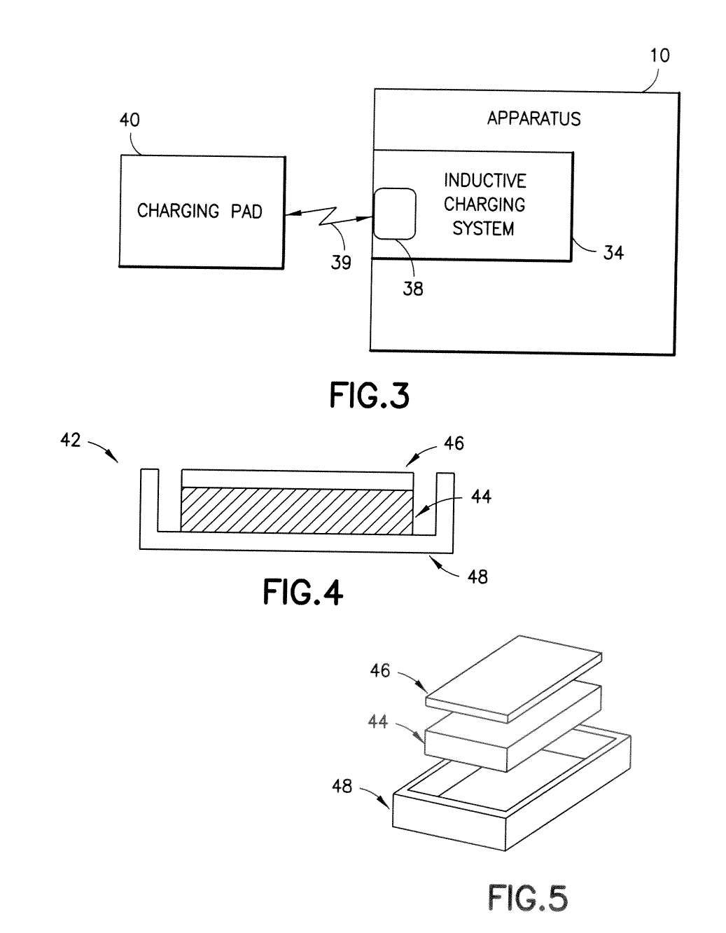

Referring also to FIG. 3, the apparatus 10 comprises an inductive charging system 34. The inductive charging system 34 provides a means to allow the rechargeable battery 26 to be recharged by use of inductive charging. Inductive charging uses an electromagnetic field to transfer energy between two objects. This is usually done with a charging station, such as charging pad 40 for example. Energy is sent through inductive coupling to an electrical device (the apparatus 10), which then can use that energy to charge battery(ies).

The inductive charging system 34 comprises an induction coil 38. This induction coil 38 cooperates with a coil in the charging station 40 to induce a current in the coil 38. This current can be used to recharge the battery 26. Because there is a small gap between the two coils employed in each of the sender and receiver of the energy within one respective devices, inductive charging is considered a short-distance “wireless” energy transfer, because it frees the user from having to deal with wires between the two devices.

Referring also to FIGS. 4-5, a magnet assembly 42 of the sound transducer 32 of the earpiece is schematically shown which includes a permanent magnet 44 and pole pieces 46, 48. In an alternate example the magnet may comprise an electromagnet, and features as described herein may be used with another component other than the magnet assembly of the earpiece, such as the magnet assembly of a speaker for example. The magnet may comprises one or more magnets. The pole pieces may comprises two or more pole pieces.

The second pole piece 48, such as formed of iron for example, forms an outer part (“pot”). The magnet 44 may be a neodymium magnet for example. The first pole piece 46 forms a top plate in this example, such as formed of iron for example. The top plate 46 may merely be a planar flat plate. The top plate and pot may be formed of iron with anticorrosive plating, such as nickel or zinc, and the magnet may be made of a neodymium alloy. This is merely an example of a magnet assembly. The apparatus may have other types of magnet assemblies, or other types of audio transducers, or other types of components to be protected from eddy current heating during inductive charging.

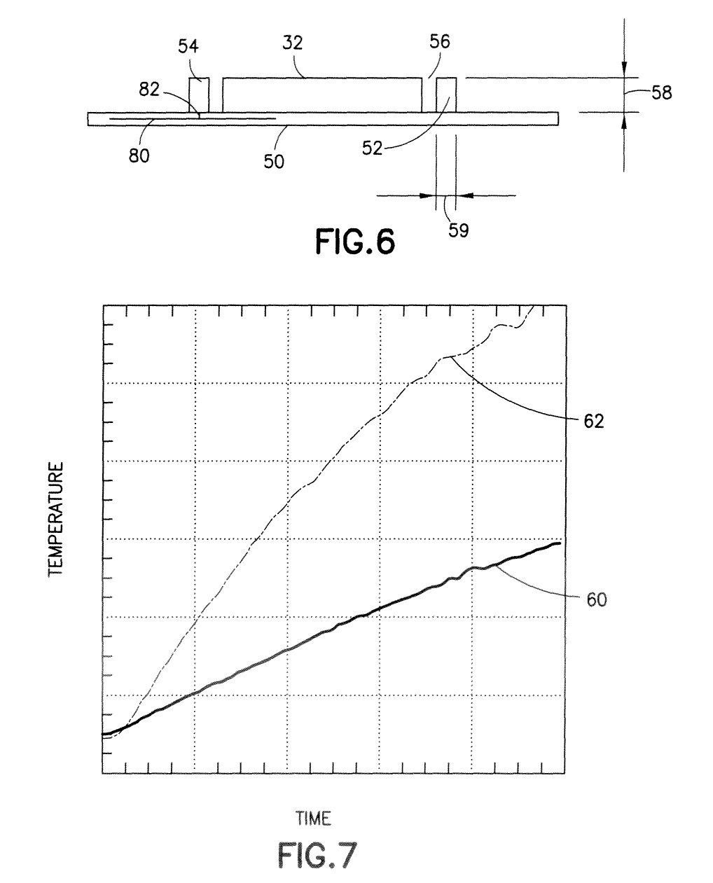

FIG. 6 is schematic sectional view showing the audio transducer 32 mounted on a substrate 50 and having an eddy current heating reduction system 52. The substrate 50 may be a printed circuit board or a device housing for example. In this example the eddy current heating reduction system 52 comprises a member 51 at least partially surrounding the component 32 to be protected. The member 54 in this example is a shielding ring which surrounds the component 32. In this example the component 32 is an audio transducer. The member 54 comprises a material which has an electrical conductivity that is higher than an electrical conductivity of a first material of the component 32. The member 54 is configured to allow an induced current density to be formed in the member 54, from the magnetic fields 39 (see FIG. 3), which is higher than an induced current density formed in the component 32 from the magnetic fields. This reduces induced eddy current heating in the component 32 by the magnetic fields. The member 54 may be a ring, for example, mounted on the substrate 50. The height 58 of the member 54 may be approximately equal to or greater than the height of the component 32. In this example a space or gap 56 is provided between the component 32 and the member 54. The space 56 may be an air gap, and/or filled with thermally and electrically insulating material. If the gap 56 between the shielding ring 54 and the audio transducer 32 is significantly larger than the height of the ring (i.e. typically more than a couple of mm), a significant fraction of the external magnetic field leaks through to the audio transducer 32. The same thing happens if the width/height ratio is changed from the suggested (i.e. a thin, wide ring is used), so phone covers, circuit board features, etc. are inefficient as shields. The shielding ring 54, in close proximity to the audio transducer 32 with a small gap 56, provides shielding which phone covers, circuit board features, etc. cannot provide.

Referring also to FIG. 7, the chart illustrates heating of two speakers placed side-by-side on an inductive charging pad. A first one of the speakers has the eddy current heating reduction system 52 with member 54. The first speaker has a temperature rise over time as illustrated by 60 because of eddy currents formed by the inductive charging pad. The second one of the speakers is identical to the first speaker, but does not have the eddy current heating reduction system 52 with member 54. The second speaker has a temperature rise over time as illustrated by 62 because of eddy currents formed by the inductive charging pad. As can be seen, because of the eddy current heating reduction system 52, heating of the first component by magnetic fields from the inductive charging pad is greatly reduced versus the component not having the eddy current heating reduction system 52.

Features as describe herein may relate to an audio transducer; especially to dynamic loudspeakers and earpieces, and their use in portable devices where inductive charging is used. A problem that has become apparent with the introduction of inductive charging is that many metal parts, including loudspeakers or earpieces, can heat substantially when placed in close proximity of the charging coil. This is due to the surface currents induced in the metal, and can cause a significant additional temperature increase in the component itself and in the interior of the device being charged.

Use of highly conductive plating or protective casing is well known in RF engineering to reduce electromagnetic interference. Use of “short circuit” rings is well known in high performance loudspeakers, but they are structurally different and for a different purpose: they are placed inside the magnet assembly and they reduce the modulation of flux in the air gap, caused by voice coil current. Such an internal ring would not have any effect on the inductive heating, and on the other hand, the benefit of an external shielding on controlling flux modulation is much smaller than that of the internal ring.

With features as describe herein, a ring or shield, such as member 54 for example, made of material with substantially higher electrical conductivity than the component to be protected, such as a loudspeaker magnet assembly for example, may be placed around the component. Most of the current caused by the external charging device may then remain within the shielding material and, as the conductivity of the material is high, the resistive losses, and thus the total thermal power of the system, are reduced as compared to the unprotected magnet assembly.

In addition to electrical conductivity as a feature as described herein, material properties for the shield may also be selected based upon magnetic properties. A combination of a copper ring with a ferrite layer (such as inside the ring) should work very efficiently. This structural modification (adding a ferrite layer) would not change the design rules for the short circuit ring 54 itself. It would just add to the efficiency. An example of such a structure is shown in FIG. 11. As shown in FIG. 11, the audio transducer 32 is surrounded by the ring 54 with a ferrite ring 55 in the gap 56. The method may comprise selecting material(s) for the member 54/55 based upon electrical conductivity of the material and/or a magnetic property of the material.

With features as described herein, a ring or cup made of highly conductive material, such as copper for example, is placed around a component that is to be protected. When placed in an alternating magnetic field, such as that produced by an inductive charger, the alternating field produces a high current density in the shield, and the magnetic field. Thus, the induced current density, is reduced in the component. This results in a reduction of inductive heating in the component itself.

As the shield itself will heat, it is advisable to avoid direct thermal contact between the shield and the component, and if possible, means for conducting heat away from the shield (e.g. via a ground plane on the circuit board, etc.) may be provided.

The thickness of the protecting material may be at least equal to the skin depth of the electromagnetic field. With a charging frequency of approximately 150 kHz a typical material thickness for copper may be 0.3-0.4 mm for example.

Features as described herein can reduce the component heating and the overall thermal load on the device. This does not require any modification of the audio component itself and, can be thus added to a design at a rather late stage.

The dimensions of a short circuit ring may be determined by two factors:
Ring width 58 may be approximately equal to (at least 80-90%) or greater than the height of the outer magnetic assembly parts of the audio transducer. In telecom transducers the height of outer magnetic assembly parts approximately equals the total component height. If the ring is narrower, there is significant leakage of magnetic field to the component and the shielding effect is reduced. For similar reasons, the gap between the ring and the transducer may be kept narrow (with typical telecom transducer dimensions less than 0.5 mm).
The thickness 59 of the ring may be determined by the “skin depth” of the material at the operating frequency. To provide adequate shielding, and no keep the heating of the ring itself to a reasonable level, the thickness may exceed the skin depth, given by expression:

$$δ = \frac{1}{\sqrt{π f μ σ}} .$$

Where μ is the magnetic permeability of the material (H/m), and σ is the electrical conductivity of the material (S/m).

In copper, magnetic permeability is approximately one, and electrical conductivity is 16.78 nΩ·m at 20° C. Substituting these values, and typical value of 100-200 kHz for the operating frequency yields 0.3-0.5 mm skin depth. Practical successful experiments were conducted with 0.5 mm thick and 2 mm wide ring at 140 kHz frequency, confirming these theoretical results. Earlier experiments with very thin, 0.1 man shields, resulted in excessive heating of the short circuit ring itself, also giving confirmation to these results.

In one example embodiment, an apparatus may be provided comprising a component comprising a first material susceptible to heating by induced eddy currents from magnetic fields generated externally from the apparatus; and an eddy current heating reduction system configured to reduce induced eddy current heating in the component by the magnetic fields, where the eddy current heating reduction system comprises a member at least partially surrounding the component, where the member comprises a second material which has an electrical conductivity that is higher than an electrical conductivity of the first material, where the member is configured to allow an induced current density to be formed in the member from the magnetic fields which is higher than an induced current density formed in the component from the magnetic fields to thereby reduce induced eddy current heating in the component by the magnetic fields.

The component may comprise a magnet assembly comprising at least two magnet assembly components. The at least two magnet assembly components may comprise at least one magnet, a first pole piece connected to a first side of the at least one magnet and a second pole piece connected to an opposite second side of the at least one magnet. The member may comprise a ring shape which at least partially surrounds the component. The member may comprise a concave shape with the component being housed at least partially inside the concave shape. The apparatus may further comprise an insulator located between the component and the member. The apparatus may further comprise a heat transfer member extending from the member of the eddy current heating reduction system, where the heat transfer member is configured to transfer heat away from the member of the eddy current heating reduction system. The heat transfer member may comprise a ground plane of a printed wiring board of the apparatus. The apparatus may comprise means for reducing eddy current generation in the component from an induction battery charging magnetic field generator.

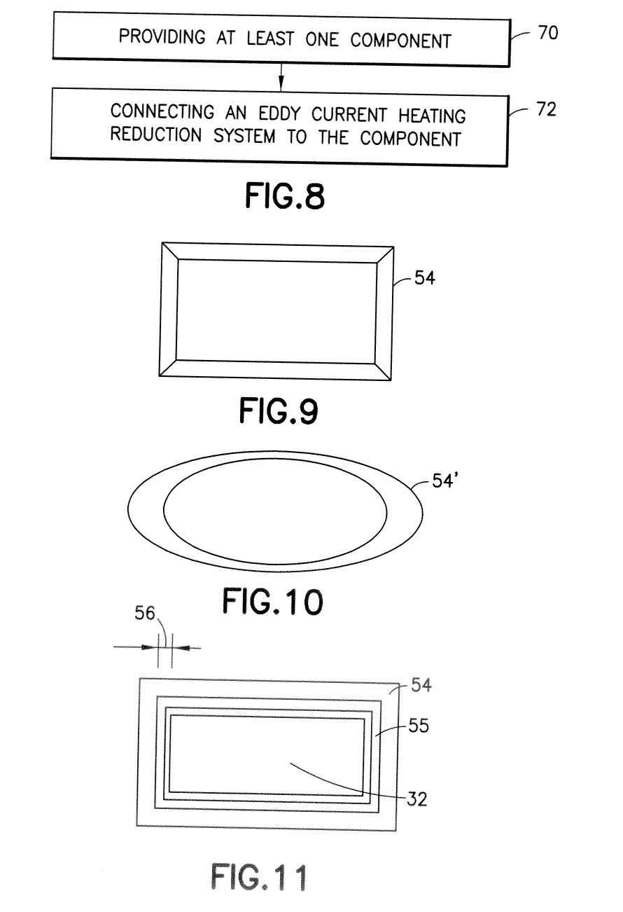

Referring also to FIG. 8, an example method may comprise providing at least one component as indicated by block 70 comprising a first material susceptible to heating by induced eddy currents from magnetic fields; and connecting an eddy current heating reduction system to the component as indicated by block 72, where the eddy current heating reduction system configured to reduce induced eddy current heating in the component by the magnetic fields, where the eddy current heating reduction system comprises a member at least partially surrounding the component, where the member comprises a second material which has an electrical conductivity that is higher than an electrical conductivity of the first material, where the member is configured to allow an induced current density to be formed in the member from the magnetic fields which is higher than an induced current density formed in the component from the magnetic fields to reduce induced eddy current heating in the component by the magnetic fields.

The at least one component may comprise providing a magnet assembly comprising at least two magnet assembly components. The at least two magnet assembly components may be provided as at least one magnet, a first pole piece connected to a first side of the at least one magnet and a second pole piece connected to an opposite second side of the at least one magnet. The member 54 may be provided as a ring shape such as shown in FIG. 9 for example which at least partially surrounds the component. The member may be provided with a concave shape 54′ such as shown in FIG. 10 for example, where the component 32 is located at least partially inside the concave shape. The method may further comprise locating an insulator 56 between the component and the member. The method may further comprise providing a heat transfer member 82 extending from the member 54 of the eddy current heating reduction system, where the heat transfer member is configured to transfer heat away from the member of the eddy current heating reduction system. The method may further comprise connecting the heat transfer member to a ground plane 80 of a printed wiring board 50.

Another example embodiment may be provided in an apparatus comprising a housing; a rechargeable battery in the housing; an induction charging system in the housing coupled to the rechargeable battery; a component in the housing, where the component comprises a first material susceptible to heating by induced eddy currents from induction charging magnetic fields generated externally from the apparatus; and an eddy current heating reduction system configured to reduce induced eddy current heating in the component by the induction charging magnetic fields, where the eddy current heating reduction system comprises a member at least partially surrounding the component, where the member comprises a second material which has an electrical conductivity that is higher than an electrical conductivity of the first material, where the member is configured to allow an induced current density to be formed in the member from the induction charging magnetic fields which is higher than an induced current density formed in the component from the induction charging magnetic fields to reduce induced eddy current heating in the component by the induction charging magnetic fields. The component may comprise a magnet assembly comprising at least two magnet assembly components including a pole piece comprised of the first material.

In one example embodiment, an audio transducer apparatus includes a component having a first material; and a heating reduction system configured to reduce induced heating in the component. The heating reduction system includes a member at least partially surrounding the component. The member includes a material which has an electrical conductivity that is higher than an electrical conductivity of the first material to thereby reduce induced heating in the component.

In one example method, a method comprises providing at least one component comprising a first material susceptible to heating by induced eddy currents from magnetic fields; and connecting a heating reduction system to the component, where the heating reduction system is configured to reduce heating in the component, where the heating reduction system comprises a member at least partially surrounding the component, where the member comprises a material which has an electrical conductivity that is higher than an electrical conductivity of the first material to reduce heating in the component.

With features as described herein, an audio transducer system could be an integral module or the member positioned around the transducer which is detachable. A dependent claim could clarify what we mean by said audio transducer system. The transducer system could be a single component or a transducer where the second material is suitably positioned relative to the transducer.

The member described above may comprise a ring shape which at least partially surrounds the component, where the member could be shaped in the shape of the transducer component. For example, some transducers can be circular shape, whereas other examples could be rectangular or elliptic shape. The member could be ring-shaped based on the shape of the transducer. In general, the transducer could be designed and integrally assembled with the member. Therefore, it could be a single component whereas in other embodiments said member could be detachable or positioned relative to the transducer component.

It should be understood that the foregoing description is only illustrative. Various alternatives and modifications can be devised by those skilled in the art. For example, features recited in the various dependent claims could be combined with each other in any suitable combination(s). In addition, features from different embodiments described above could be selectively combined into a new embodiment. Accordingly, the description is intended to embrace all such alternatives, modifications and variances which fall within the scope of the appended claims.

What is claimed is:

1. An audio transducer apparatus comprising:
a component having a first material; and
a heating reduction system configured to reduce induced heating in the component, where the heating reduction system comprises a member at least partially surrounding the component, where the member comprises a material which has an electrical conductivity that is higher than an electrical conductivity of the first material to thereby reduce induced heating in the component.

2. An audio transducer apparatus as in claim 1 where the component comprises a magnet assembly comprising at least two magnet assembly components.

3. An audio transducer apparatus as in claim 2 where the at least two magnet assembly components comprise at least one magnet, a first pole piece connected to a first side of the at least one magnet and a second pole piece connected to an opposite second side of the at least one magnet.

4. An audio transducer apparatus as in claim 1 where the member comprises at least one of:
a ring shape which at least partially surrounds the component,
a concave shape with the component being housed at least partially inside the concave shape,
a shape which at least partially surrounds the audio transducer.

5. An audio transducer apparatus as in claim 1 further comprising an insulator located between the component and the member.

6. An audio transducer apparatus as in claim 1 further comprising a heat transfer member extending from the member of the heating reduction system, where the heat transfer member is configured to transfer heat away from the member of the heating reduction system.

7. An audio transducer apparatus as in claim 6 where the heat transfer member comprises a ground plane of a printed wiring board of an apparatus.

8. An audio transducer apparatus as in claim 1 comprising means for reducing eddy current generation in the component from an induction battery charging magnetic field generator.

9. A device comprising:
a housing;
a rechargeable battery in the housing;
an induction charging system in the housing coupled to the rechargeable battery; and
an audio transducer apparatus as in claim 1 in the housing.

10. A method comprising:
providing at least one component comprising a first material susceptible to heating by induced eddy currents from magnetic fields; and
connecting a heating reduction system to the component, where the heating reduction system is configured to reduce heating in the component, where the heating reduction system comprises a member at least partially surrounding the component, where the member comprises a material which has an electrical conductivity that is higher than an electrical conductivity of the first material to reduce heating in the component.

11. A method as in claim 10 where providing the at least one component comprises providing a magnet assembly comprising at least two magnet assembly components.

12. A method as in claim 11 where the at least two magnet assembly components are provided as at least one magnet, a first pole piece connected to a first side of the at least one magnet and a second pole piece connected to an opposite second side of the at least one magnet.

13. A method as in claim 10 where the member is provided as a ring shape which at least partially surrounds the component.

14. A method as in claim 10 where the member is provided with a concave shape, where the component is located at least partially inside the concave shape.

15. A method as in claim 10 further comprising locating an insulator between the component and the member.

16. A method as in claim 10 further comprising providing a heat transfer member extending from the member of the heating reduction system, where the heat transfer member is configured to transfer heat away from the member of the heating reduction system.

17. A method as in claim 16 further comprising connecting the heat transfer member to a ground plane of a printed wiring board.

18. A method as in claim 10 further comprising selecting material for the member based upon electrical conductivity of the material and/or a magnetic property of the material.

19. An apparatus comprising:
a housing;
a rechargeable battery in the housing;
an induction charging system in the housing coupled to the rechargeable battery;
a component in the housing, where the component comprises a first material susceptible to heating by induced eddy currents from induction charging magnetic fields generated externally from the apparatus; and
an eddy current heating reduction system configured to reduce induced eddy current heating in the component by the induction charging magnetic fields, where the eddy current heating reduction system comprises a member at least partially surrounding the component, where the member comprises a second material which has an electrical conductivity that is higher than an electrical conductivity of the first material, where the member is configured to allow an induced current density to be formed in the member from the induction charging magnetic fields which is higher than an induced current density formed in the component from the induction charging magnetic fields to reduce induced eddy current heating in the component by the induction charging magnetic fields.

20. An apparatus as in claim 19 where the component comprises a magnet assembly comprising at least two magnet assembly components including a pole piece comprised of the first material.
